(19) United States
(12) Patent Application Publication
(10) Pub. No.: US 2025/0322886 A1
(43) Pub. Date: Oct. 16, 2025

(54) MEMORY DEVICE AND OPERATING METHOD THEREOF

(71) Applicant: TAIWAN SEMICONDUCTOR MANUFACTURING COMPANY, LTD., Hsinchu (TW)

(72) Inventors: Sheng-Chih LAI, Hsinchu County (TW); Chen-Jun WU, Hsinchu City (TW)

(73) Assignee: TAIWAN SEMICONDUCTOR MANUFACTURING COMPANY, LTD., Hsinchu (TW)

(21) Appl. No.: 18/635,911

(22) Filed: Apr. 15, 2024

(51) Int. Cl. G11C 16/26; G11C 16/24

(52) U.S. Cl. CPC G11C 16/26; G11C 16/24

(57) ABSTRACT

A method includes: charging a bit line to a read voltage level; coupling the bit line to a memory element; and adjusting a voltage level of the bit line from the read voltage level according to a data bit stored in the memory element. The read voltage level is smaller than a coercive voltage level of the memory element.

### BACKGROUND

A memory device performs a read operation. However, a memory state of the memory device is destroyed after the read operation, and a write-back operation following the read operation is needed. During a compute-in-memory (CiM) operation, the memory state for each memory cell cannot be identified after charge sharing. In other words, the memory states corresponding to CiM weights are loss after CiM computing.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a memory device, in accordance with some embodiments of the present disclosure.

FIG. 2 is a timing diagram of voltage levels of the word lines, the bit lines and the plate line shown in FIG. 1 during the read operation, in accordance with some embodiments of the present disclosure.

FIG. 3 is a schematic diagram of relationship between voltage difference between two terminals of the memory element and polarization of the memory element, in accordance with some embodiments of the present disclosure.

FIG. 4A is a schematic diagram of equivalent capacitors of a bit line and corresponding memory cells during a destructive read, in accordance with some embodiments of the present disclosure.

FIG. 4B is a schematic diagram of equivalent capacitors of a bit line and corresponding memory cells during a non-destructive read, in accordance with some embodiments of the present disclosure.

FIG. 5A is a timing diagram of voltage levels of the word lines, the bit lines and the plate line shown in FIG. 1 during a write operation, in accordance with some embodiments of the present disclosure.

FIG. 5B is a schematic diagram of relationship between voltage difference between two terminals of the memory element and polarization of the memory element during a write operation for writing a first logic value, in accordance with some embodiments of the present disclosure.

FIG. 5C is a schematic diagram of relationship between voltage difference between two terminals of the memory element and polarization of the memory element during a write operation for writing the first logic value, in accordance with some embodiments of the present disclosure.

FIG. 5D is a schematic diagram of relationship between voltage difference between two terminals of the memory element and polarization of the memory element during a write operation for writing a second logic value, in accordance with some embodiments of the present disclosure.

FIG. 5E is a schematic diagram of relationship between voltage difference between two terminals of the memory element and polarization of the memory element during a write operation for writing the second logic value, in accordance with some embodiments of the present disclosure.

FIG. 6A is a cross section diagram of a memory device corresponding to the memory device shown in FIG. 1, in accordance with some embodiments of the present disclosure.

FIG. 6B is a cross section diagram of the memory device along a line shown in FIG. 6A, in accordance with some embodiments of the present disclosure.

FIG. 6C is a layout diagram of the memory device shown in FIG. 6A, in accordance with some embodiments of the present disclosure.

FIG. 7A is a flowchart diagram of a method operating at least one of the semiconductor devices and shown in FIG. 1 and FIG. 6A, in accordance with some embodiments of the present disclosure.

FIG. 7B is a flowchart diagram of a method operating at least one of the semiconductor devices and shown in FIG. 1 and FIG. 6A, in accordance with some embodiments of the present disclosure.

FIG. 8 is a schematic view of a system for designing and manufacturing of at least one of the semiconductor devices and shown in FIG. 1 and FIG. 6A, in accordance with some embodiments of the present disclosure.

FIG. 9 is a block diagram of an integrated circuit (IC)/semiconductor device manufacturing system, and an IC manufacturing flow associated therewith, in accordance with some embodiments of the present disclosure.

### DETAILED DESCRIPTION

The following disclosure provides many different embodiments, or examples, for implementing different features of the provided subject matter. Specific examples of components, materials, values, steps, arrangements or the like are described below to simplify the present disclosure. These are, of course, merely examples and are not intended to be limiting. Other components, materials, values, steps, arrangements or the like are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The terms applied throughout the following descriptions and claims generally have their ordinary meanings clearly established in the art or in the specific context where each term is used. Those of ordinary skill in the art will appreciate that a component or process may be referred to by different names. Numerous different embodiments detailed in this specification are illustrative only, and in no way limits the scope and spirit of the disclosure or of any exemplified term.

It is worth noting that the terms such as “first” and “second” used herein to describe various elements or processes aim to distinguish one element or process from another. However, the elements, processes and the sequences thereof should not be limited by these terms. For example, a first element could be termed as a second element, and a second element could be similarly termed as a first element without departing from the scope of the present disclosure.

In the following discussion and in the claims, the terms “comprising,” “including,” “containing,” “having,” “involving,” and the like are to be understood to be open-ended, that is, to be construed as including but not limited to. As used herein, instead of being mutually exclusive, the term “and/or” includes any of the associated listed items and all combinations of one or more of the associated listed items.

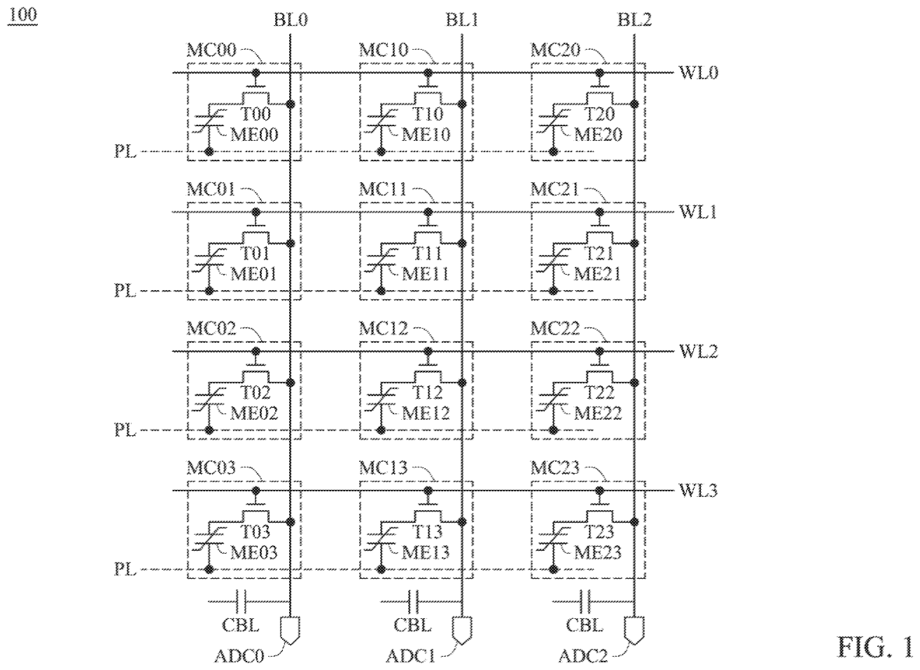

FIG. 1 is a schematic diagram of a memory device 100, in accordance with some embodiments of the present disclosure. As illustratively shown in FIG. 1, the memory device 100 includes memory cells MC00-MC03, MC10-MC13, MC20-MC23, converters ADC0-ADC2, word lines WL0-WL3, bit lines BL0-BL2 and a plate line PL. The embodiments of the present disclosure are not limited to this. In various embodiments, the memory device 100 includes various numbers of memory cells, converters, word lines and bit lines.

In some embodiments, each of the memory cells MC00-MC03, MC10-MC13 and MC20-MC23 is configured to store a corresponding data bit. The converters ADC0-ADC2 are configured to convert signals associated with the data bits to read the data bits. In some embodiments, the converters ADC0-ADC2 are implemented by analog to digital converters.

As illustratively shown in FIG. 1, each of the memory cells MC00-MC03, MC10-MC13 and MC20-MC23 includes a corresponding switch and a corresponding memory element. Specifically, the memory cell MC00 includes a switch T00 and a memory element ME00. The memory cell MC01 includes a switch T01 and a memory element ME01. The memory cell MC11 includes a switch T11 and a memory element ME11, and so on. The memory cell MC23 includes a switch T23 and a memory element ME23. In some embodiments, the switches T00-T23 are implemented by transistors, and the memory elements ME00-ME23 are implemented by variable capacitors, such as ferroelectric capacitors, which store logic values by polarizations.

As illustratively shown in FIG. 1, first terminals of the switches T00-T03 are coupled to the bit line BL0, first terminals of the switches T10-T13 are coupled to the bit line BL1, and first terminals of the switches T20-T23 are coupled to the bit line BL2. Second first terminals of the switches T00-T23 are coupled to first terminals of the memory elements ME00-ME23, respectively. Each of second terminals of the memory elements ME00-ME23 is coupled to the plate line PL. Control terminals of the switches TOO, T10 and T20 are coupled to the word line WL0, control terminals of the switches T01, T11 and T21 are coupled to the word line WL1, control terminals of the switches T02, T12 and T22 are coupled to the word line WL2, and control terminals of the switches T03, T13 and T23 are coupled to the word line WL3.

In some embodiments, during a read operation, the converter ADC0 is configured to convert a bit line signal of the bit line BL0 into a digital signal. The converter ADC1 is configured to convert a bit line signal of the bit line BL1 into a digital signal. The converter ADC2 is configured to convert a bit line signal of the bit line BL2 into a digital signal.

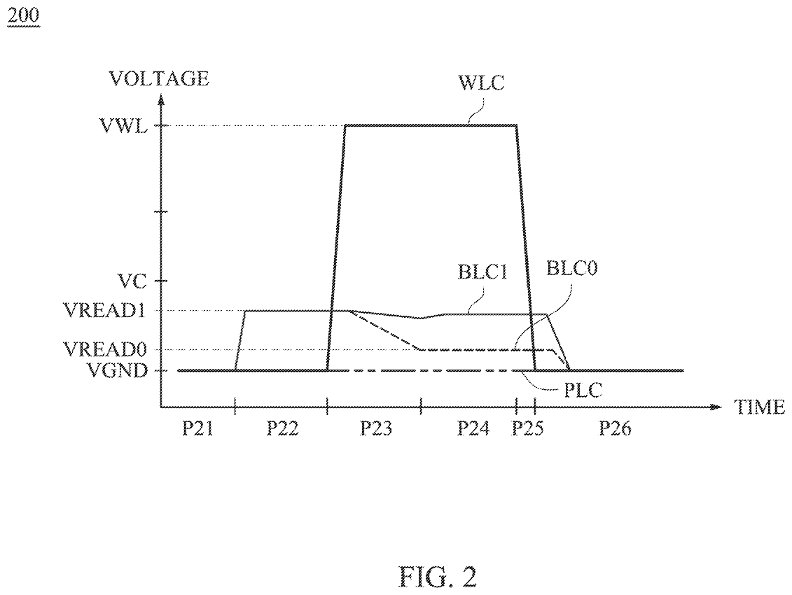

As illustratively shown in FIG. 1, each of the bit lines BL0-BL2 has an equivalent capacitor CBL. During the read operation, the memory elements ME00-ME23 share charges with the capacitors CBL, to adjust voltage levels of the bit line signals of the bit lines BL0-BL2 according to logic values stored by the memory elements ME00-ME23. Further details of the read operation are described below with the embodiments associated with FIG. 2.

FIG. 2 is a timing diagram 200 of voltage levels of the word lines, the bit lines and the plate line shown in FIG. 1 during the read operation, in accordance with some embodiments of the present disclosure. A horizontal axis of the timing diagram 200 corresponds to time, and a vertical axis of the timing diagram 200 corresponds to voltage. As illustratively shown in FIG. 2, the timing diagram 200 includes periods P21-P26 arranged continuously in order.

In some embodiments, during the read operation, multiple word lines activated to turn on switches in corresponding memory cells. Referring to FIG. 1 and FIG. 2, in the embodiment shown in FIG. 2, during the read operation, the word lines WL0-WL3 are activated to turn on switches T00-T23. However, the embodiments of present disclosure are not limited to this. In various embodiments, various numbers of word lines are activated.

As illustratively shown in FIG. 2, the timing diagram 200 includes curves WLC, BLC0, BLC1 and PLC. For illustration purpose, the curve WLC corresponds to voltage levels of the word lines WL0-WL3, the curves BLC0 and BLC1 correspond to voltage levels of the bit line BL1, and the curve PLC corresponds to voltage levels of the plate line PL. However, the embodiments of present disclosure are not limited to this. For example, in other embodiments, the curves BLC0 and BLC1 correspond to voltage levels of the bit line BL0 or the bit line BL2.

Referring to FIG. 1 and FIG. 2, the curve BLC0 corresponds to a condition that each the memory elements ME10-ME13 stores the logic value 0, and the curve BLC1 corresponds to a condition that each the memory elements ME10-ME13 stores the logic value 1.

During the period P21, the memory device 100 is in a standby state. Accordingly, each of the word lines WL0-WL3, the bit line BL1 and the plate line PL has a ground voltage level VGND, such that the switches T10-T13 are turned off.

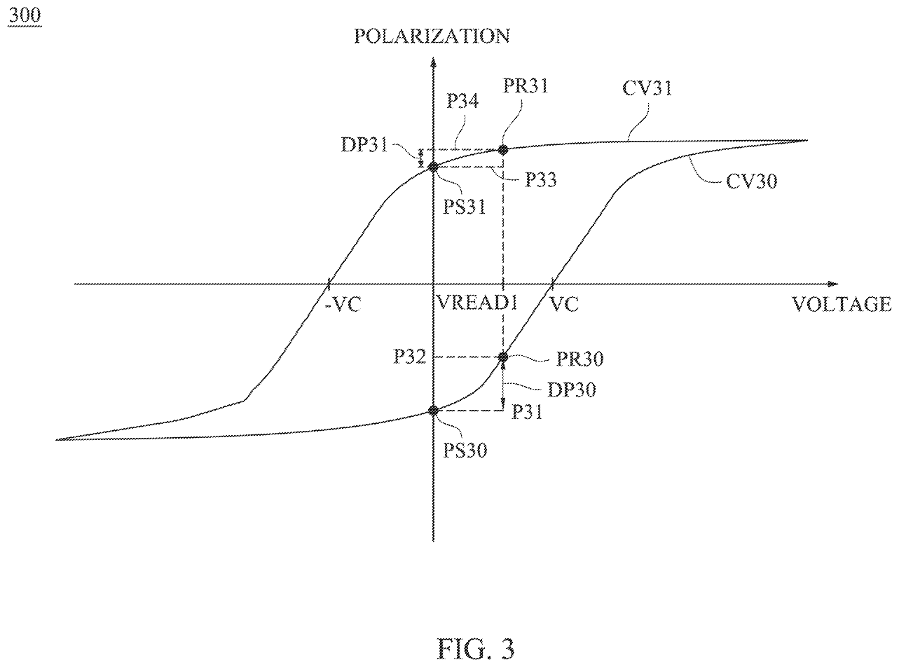

During the period P22, the bit line BL1 is precharged to a read voltage level VREAD1, and the word lines WL0-WL3 are maintained at the ground voltage level VGND, such that the switches T10-T13 are turned off. It is noted that the read voltage level VREAD1 is smaller than a coercive voltage level VC. Further details of the coercive voltage level VC are described below with embodiments associated with FIG. 3. In some embodiments, during the period P22, the bit lines BL0 and BL2 are also precharged to the read voltage level VREAD1.

During the period P23, the word lines WL0-WL3 are raised to an enable voltage level VWL, to turn on the switches T00-T23. Specifically, the switches T10-T13 are turned on, such that the bit line BL1 shares charges with the memory elements ME10-ME13. Accordingly, the voltage level of the bit line BL1 is adjusted according to the logic values stored in the memory elements ME10-ME13.

Referring to the curve BLC1, in response to each of the memory elements ME10-ME13 storing the logic value 1, the bit line BL1 is maintained at the read voltage level VREAD1. Referring to the curve BLC0, in response to each of the memory elements ME10-ME13 storing the logic value 0, the bit line BL1 is adjusted to the read voltage level VREAD0. In some embodiments, the read voltage level VREAD0 is smaller than the read voltage level VREAD1.

In some embodiments, the memory elements ME10-ME13 store at least one logic value 0 and at least one logic value 1. In such embodiments, the bit line BL1 is adjusted to a voltage level between the voltage levels VREAD0 and VREAD1. In response to a quantity of the logic value 1 being larger, the voltage level is closer to the voltage level VREAD1. In response to a quantity of the logic value 0 being larger, the voltage level is closer to the voltage level VREAD0.

During the period P24, the converters ADC0-ADC2 are enabled to sense the corresponding bit lines BL0-BL2. Specifically, the converter ADC1 senses the bit line BL1. In the condition corresponding to the curve BLC0, the bit line BL1 is maintained at the read voltage level VREAD0. In the condition corresponding to the curve BLC1, the bit line BL1 is maintained at the read voltage level VREAD1.

During the period P25, the word lines WL0-WL3 are adjusted to the ground voltage level VGND, to turn off the switches T00-T23. Specifically, the switches T10-T13 are turned off, such that the bit line BL1 stop to share charges with the memory elements ME10-ME13.

During the period P26, the memory device 100 is back to the standby state. Accordingly, the bit line BL1 is adjusted to the ground voltage level VGND. In some embodiments, after the period P26, the operations of the period P22-P25 is performed again for another read operation.

In some embodiments, during the reading operation, the voltage level of the bit line BL0 corresponds to a summation of the logic values stored in the memory elements ME00-ME03, the voltage level of the bit line BL1 corresponds to a summation of the logic values stored in the memory elements ME10-ME13, and the voltage level of the bit line BL2 corresponds to a summation of the logic values stored in the memory elements ME20-ME23. Accordingly, the reading operation is referred to as a compute-in-memory (CiM) operation.

FIG. 3 is a schematic diagram 300 of relationship between voltage difference between two terminals of the memory element and polarization of the memory element, in accordance with some embodiments of the present disclosure. A horizontal axis of the schematic diagram 300 corresponds to voltage level, and a vertical axis of the schematic diagram 300 corresponds to polarization. In some embodiments, a unit of the voltage level is volt, and a unit of the polarization is micro-coulomb per centimeter square (μC/cm²).

Referring to FIG. 1 and FIG. 3, for illustration purpose, the voltage difference and polarization of the memory element ME11 are described following as an example for the schematic diagram 300. However, the present disclosure is not limited to this. The features described by the schematic diagram 300 are also suitable for other memory elements.

As illustratively shown in FIG. 3, the schematic diagram 300 includes curves CV31 and CV30. The state of the memory element ME11 is changed along the curves CV31 and CV30 when the voltage difference between two terminals of the memory element ME11 is changed. The polarization of the memory element ME11 is increased in response to increasing of the voltage difference. When an absolute value of the voltage difference between two terminals of the memory element ME11 is equal to the coercive voltage level VC, the polarization of the memory element ME11 is equal to a zero voltage level.

In some embodiments, during the read operation, the plate line PL coupled to the memory element ME11 is maintained at the ground voltage level VGND. Accordingly, the voltage difference between two terminals of the memory element ME11 corresponds to the voltage level of the bit line BL1.

As illustratively shown in FIG. 3, the curve CV30 includes points PS30 and PR30, and the curve CV31 includes points PS31 and PR31. At the point PS30, the plate line PL has the ground voltage level VGND and the switch T11 is turned off, such that the voltage difference between two terminals of the memory element ME11 is the zero voltage level. Accordingly, the memory element ME11 has a polarization P31 to store the logic value 0.

During the read operation, the switch T11 is turned on and the bit line BL1 has the read voltage level VREAD1, such that the voltage difference between two terminals of the memory element ME11 is the read voltage level VREAD1. Accordingly, the state of the memory element ME11 is changed from the point PS30 to the point PR30, such that the memory element ME11 has a polarization P32. In some embodiments, the polarization P32 is smaller than zero and larger than the polarization P31.

After the read operation, the switch T11 is turned off, such that the voltage difference between two terminals of the memory element ME11 is back to zero. Accordingly, the state of the memory element ME11 is changed from the point PR30 to the point PS30. Referring to FIG. 2 and FIG. 3, the point PS30 corresponds to the periods P21 and P26, and point PR30 corresponds to the period P23.

Similarly, at the point PS31, the plate line PL has the ground voltage level VGND and the switch T11 is turned off, such that the voltage difference between two terminals of the memory element ME11 is zero. The memory element ME11 has a polarization P33 to store the logic value 1.

During the read operation, the switch T11 is turned on and the bit line BL1 has the read voltage level VREAD1, such that the voltage difference between two terminals of the memory element ME11 is the read voltage level VREAD1. Accordingly, the state of the memory element ME11 is changed from the point PS31 to the point PR31, such that the memory element ME11 has a polarization P34. In some embodiments, the polarization P33 is smaller than the polarization P34 and larger than zero.

After the read operation, the switch T11 is turned off, such that the voltage difference between two terminals of the memory element ME11 is back to zero. Accordingly, the state of the memory element ME11 is changed from the point PR31 to the point PS31. Referring to FIG. 2 and FIG. 3, the point PS31 corresponds to the periods P21 and P26, and point PR31 corresponds to the period P23.

In some approaches, during a read operation, a bit line coupled to a memory element has a read voltage level larger than a coercive voltage level, such that the memory element is switched from the logic value 0 to the logic value 1. Alternatively stated, a destructive read is performed. As a result, the logic value 0 cannot be restore in CiM operation.

Compared to above approaches, in some embodiments of preset disclosure, during the read operation, the bit line BL1 coupled to the memory element ME11 has the read voltage level VREAD1 which is smaller than the coercive voltage level VC, such that the logic value stored in the memory element ME11 is not lost after CiM operation and can be re-used for next CiM operation.

In some embodiments, the read voltage level VREAD1 is within a range from 0.3 times the coercive voltage level VC to 0.8 times the coercive voltage level VC. The read voltage level VREAD1 is dependent on sensing resolution of the converters ADC0-ADC2, polarization-voltage (P-V) curves (such as the curves CV30 and CV31) of the memory elements ME00-ME23 and cell number per bit line.

Referring to FIG. 1 and FIG. 3, for illustration purpose, the features of the converter ADC1, the bit line BL1 and the memory elements ME10-ME13, especially the memory element ME11 are described following as an example for the read voltage level VREAD1. However, the present disclosure is not limited to this. The features associated with the read voltage level VREAD1 are also suitable for other converters, other bit lines and other memory elements.

In some embodiments, the sensing resolution of the converter is for distinguishing different summation value of the logic values stored in the memory elements ME10-ME13. Each of the memory elements ME10-ME13 stores the logic value 0 or 1. The summation value is one of the logic values 0, 1, 2, 3 and 4.

Referring to FIG. 2, the voltage levels VREAD0 and VREAD1 correspond to the summation values 0 and 4, respectively. Three voltage levels between voltage levels VREAD0 and VREAD1 correspond to the summation values 1, 2 and 3, respectively.

In order to distinguish the summation values 0-4 from each other, the converter ADC1 has a sensing resolution that can distinguish the five voltage levels described above. When the sensing resolution of the converter ADC1 too low to distinguish the five voltage levels, the voltage level VREAD1 is increased to enlarge differences between the five voltage levels. Alternatively stated, when the sensing resolution of the converter ADC1 is higher, a lower voltage level VREAD1 can be used. In some embodiment, when the sensing resolution of the converter ADC1 is increased, the voltage level VREAD1 is decrease. When the sensing resolution of the converter ADC1 is decreased, the voltage level VREAD1 is increase.

For example, when the converter ADC1 has a first sensing resolution, the read voltage level VREAD1 has a first value. When the converter ADC1 has a second sensing resolution higher than the first sensing resolution, the read voltage level VREAD1 has a second value lower than the first value.

Regarding relationships between the P-V curves CV30, CV31 and the read voltage level VREAD1, a signal differentiation SD3 associated with the curves CV30, CV31 is calculated by a processor for determining the read voltage level VREAD1. Specifically, a polarization difference DP30 is equal to a difference between the polarizations P31 and P32, and a polarization difference DP31 is equal to a difference between the polarizations P33 and P34. The signal differentiation SD3 is equal to the polarization difference DP30 minus the polarization difference DP31, that is, SD3=DP30−DP31.

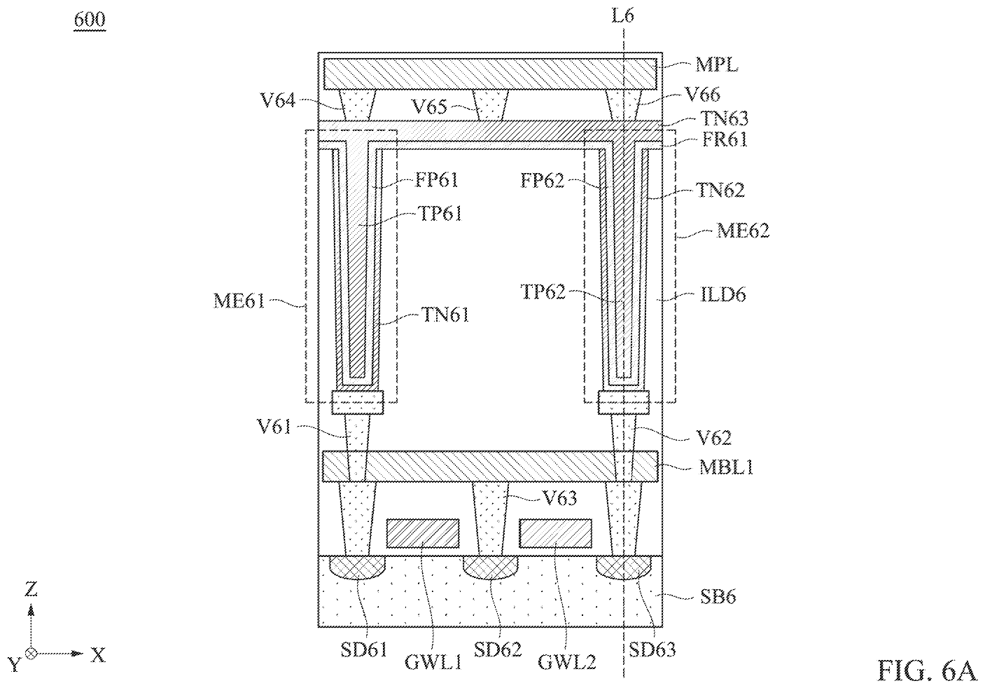

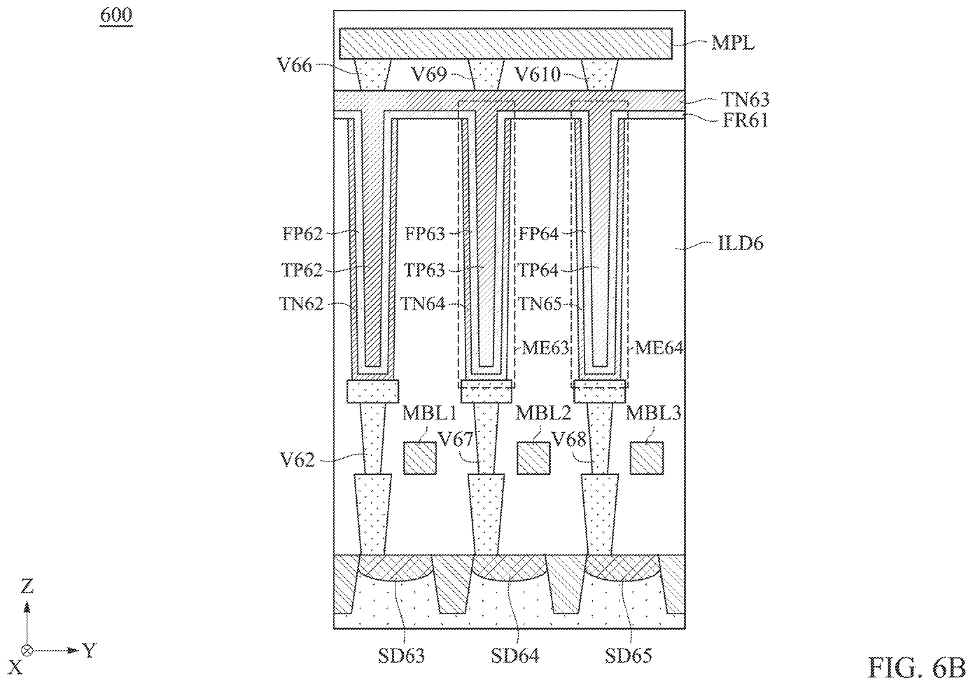

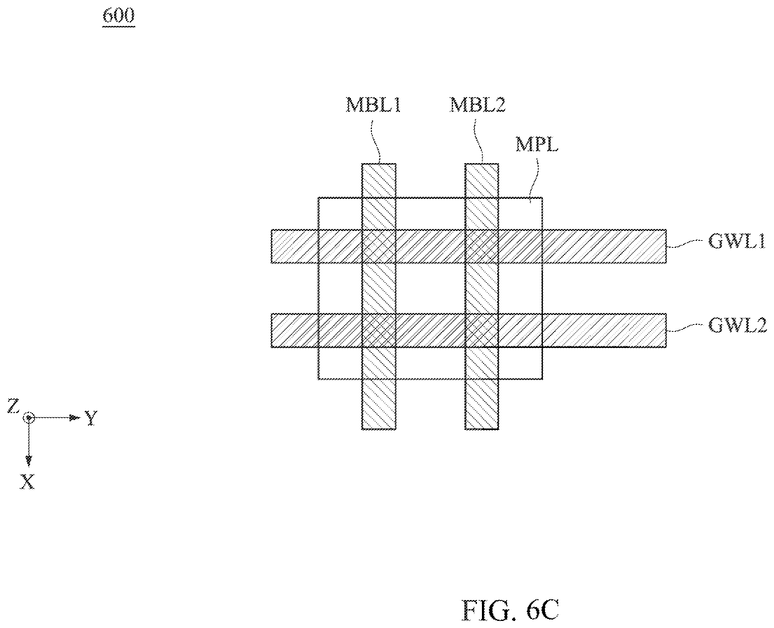

In some embodiments, for different structure of the memory element ME11, the curves CV30 and CV31 have different shape. When a difference between the curves CV30 and CV31 is smaller, the signal differentiation SD3 is smaller. When the difference between the curves CV30 and CV31 is larger, the signal differentiation SD3 is larger. Further details of the structure of the memory element ME11 is described below with the embodiments associated with FIG. 6A.

For example, when a polarization difference between the polarizations P31 and P34 has a first polarization difference value (that is, the difference between the curves CV30 and CV31 is small), the signal differentiation SD3 has a first differentiation value. When the polarization difference between the polarizations P31 and P34 has a second polarization difference value larger than the first differentiation value (that is, the difference between the curves CV30 and CV31 is large), the signal differentiation SD3 has a second differentiation value larger than the first differentiation value. In some embodiments, a larger signal differentiation SD3 is good for a lower read voltage level VREAD1. Alternatively stated, the lower read voltage level VREAD1 corresponds to the larger signal differentiation SD3. In some embodiment, when the signal differentiation SD3 is increased, the voltage level VREAD1 is decrease. When the signal differentiation SD3 is decreased, the voltage level VREAD1 is increase.

Accordingly, in some embodiments, in response to the signal differentiation SD3 having the first differentiation value, the read voltage level VREAD1 has a first value. In response to the signal differentiation SD3 having the second differentiation value larger than the first differentiation value, the read voltage level VREAD1 has a second value smaller than the first value. In some embodiments, the read voltage level VREAD1 is determined after the curves CV30 and CV31 are obtained by measuring the memory element ME11.

Regarding relationships between the cell number per bit line and the read voltage level VREAD1, when the cell number per bit line is increased, more cells can be used for storing a same data bit. Accordingly, the memory device 100 has a higher sensing window (that is, the difference between the voltage levels VREAD1 and VREAD0) for the sensing resolution of the converter ADC1, and the read voltage level VREAD1 can be reduced. In some embodiments, the cell number of a bit line is a quantity of memory cells coupled to the bit line during the read operation.

For example, in a condition that the cell number of the bit line BL1 is two, that is, only the memory cells MC10 and MC11 are coupled to the bit line BL1, one memory cell is used to store one data bit. During the read operation, the two memory elements ME10 and ME11 share charges with the bit line BL1. Accordingly, the difference between the voltage levels VREAD1 and VREAD0 is small, and a larger read voltage level VREAD1 is for satisfying the sensing resolution of the converter ADC.

Compared to the condition described above, condition that the cell number of the bit line BL1 is four, that is, the memory cells MC10-MC13 are coupled to the bit line BL1, two memory cells are used to store one data bit. During the read operation, the four memory elements ME10-MC13 share charges with the bit line BL1. Accordingly, the difference between the voltage levels VREAD1 and VREAD0 is larger, and the read voltage level VREAD1 can be smaller.

In some embodiments, in response to the bit line BL1 has a first cell number, the read voltage level VREAD1 has a first value. In response to the bit line BL1 has a second cell number larger than the first cell number, the read voltage level VREAD1 has a second value smaller than the first value. In some embodiments, when the cell number of the bit line BL1 is increased, the read voltage level VREAD1 is decreased. When the cell number of the bit line BL1 is decreased, the read voltage level VREAD1 is increased.

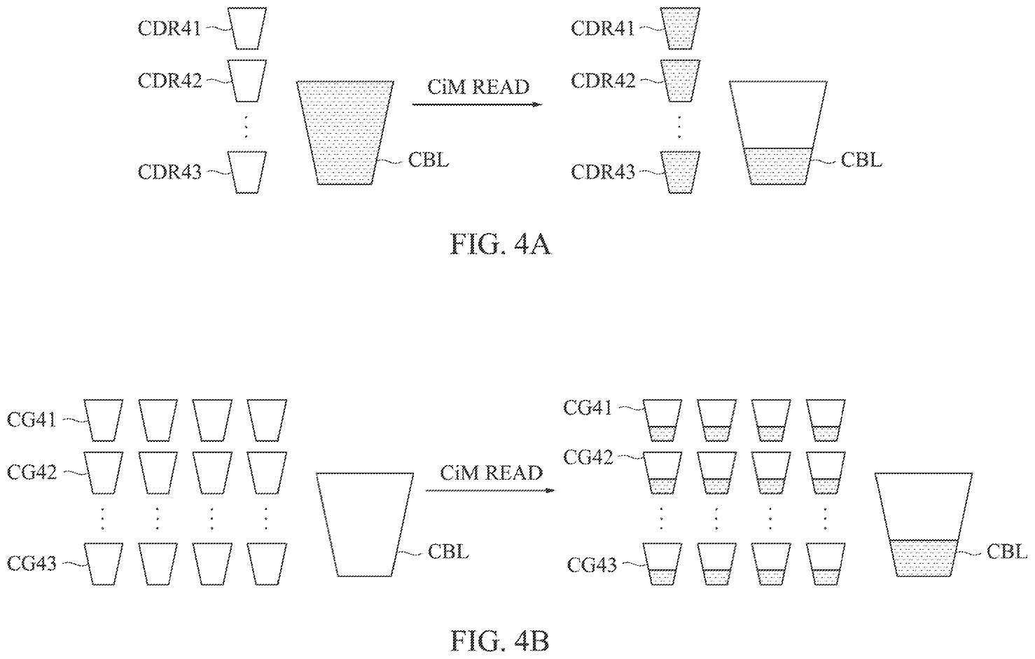

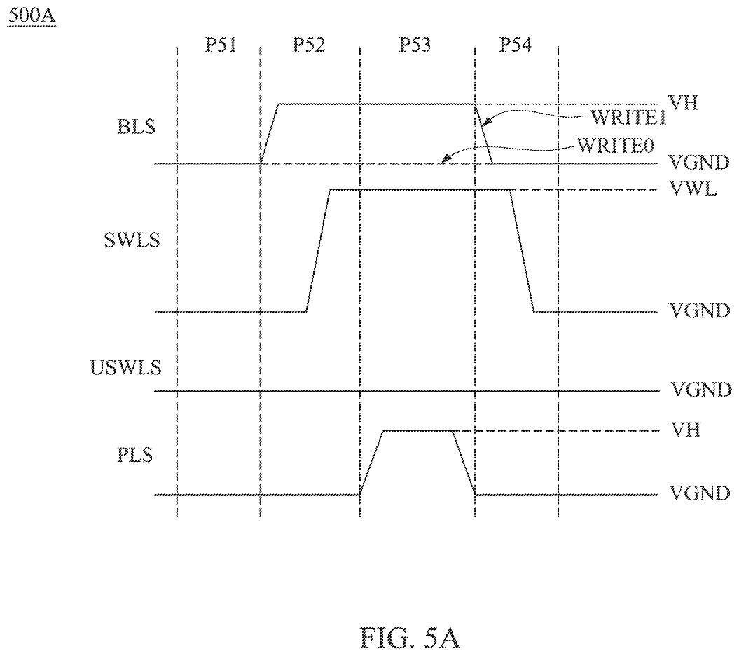

FIG. 4A is a schematic diagram 400A of equivalent capacitors of a bit line and corresponding memory cells during a destructive read, in accordance with some embodiments of the present disclosure. As illustratively shown in FIG. 4A, the schematic diagram 400A includes capacitors CDR41-CDR43 and CBL. The capacitor CBL corresponds to an equivalent capacitor of a bit line, and the capacitors CDR41-CDR43 correspond to equivalent capacitors of memory cells coupled to the bit line. In various embodiments, various number of memory cells are coupled to the bit line.

For example, referring to FIG. 4A and FIG. 1, the capacitor CBL corresponds to the equivalent capacitor of the bit line BL1, and the capacitors CDR41-CDR43 correspond to equivalent capacitors of memory elements ME10, ME11 and ME13, respectively.

As illustratively shown in FIG. 4A, before a CiM read operation, the capacitor CBL stores charges and does not share the charges with the capacitors CDR41-CDR43. After the CiM read operation is performed, the capacitor CBL shares the charges with the capacitors CDR41-CDR43.

FIG. 4B is a schematic diagram 400B of equivalent capacitors of a bit line and corresponding memory cells during a non-destructive read, in accordance with some embodiments of the present disclosure. As illustratively shown in FIG. 4B, the schematic diagram 400B includes capacitor groups CG41-CG43 and the capacitor CBL. The capacitor CBL corresponds to an equivalent capacitor of a bit line, and the capacitor groups CG41-CG43 correspond to equivalent capacitors of memory cells coupled to the bit line.

As illustratively shown in FIG. 4B, each of the capacitor groups CG41-CG43 includes multiple capacitors, such as four capacitors. Each of the capacitors corresponding to one memory cell. Before the CiM read operation, the capacitor CBL stores charges and does not share the charges with the capacitor groups CG41-CG43. After the CiM read operation is performed, the capacitor CBL shares the charges with the capacitors CDR41-CDR43.

Referring to FIG. 4A and FIG. 4B, the per-cell sensing window corresponding to the signal differentiation SD3 of the non-destructive read is approximately 0.2 times to 0.25 times of the destructive read. To balance the per-cell sensing window loss in the non-destructive read, 4 times to 5 times memory cells per bit line (that is, the cell number of the bit line) is adopted.

In the embodiments shown in FIG. 4A and FIG. 4B, the capacitor group CG41 stores charges of the capacitor CDR41, the capacitor group CG42 stores charges of the capacitor CDR42, and the capacitor group CG43 stores charges of the capacitor CDR43. Accordingly, by increasing the cell number, the sensing window is increased.

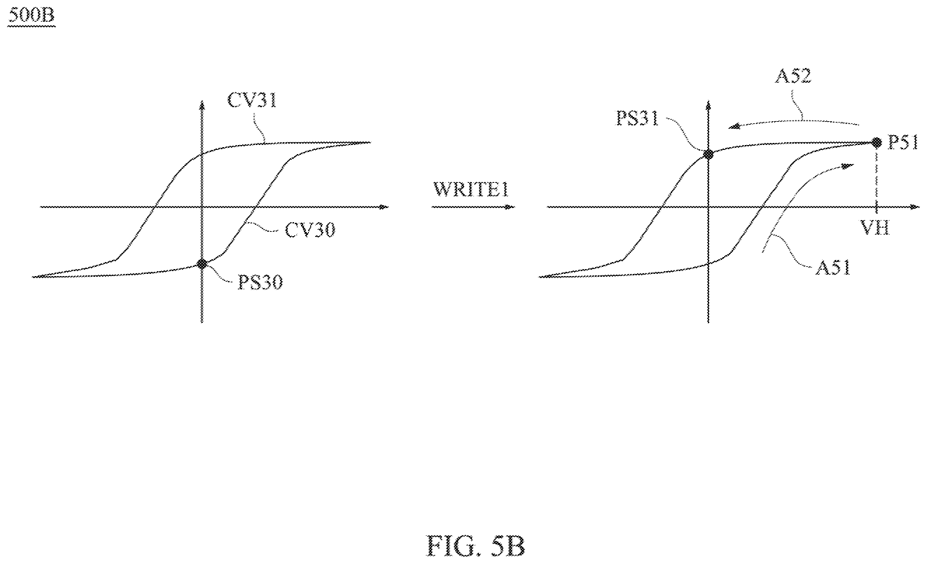

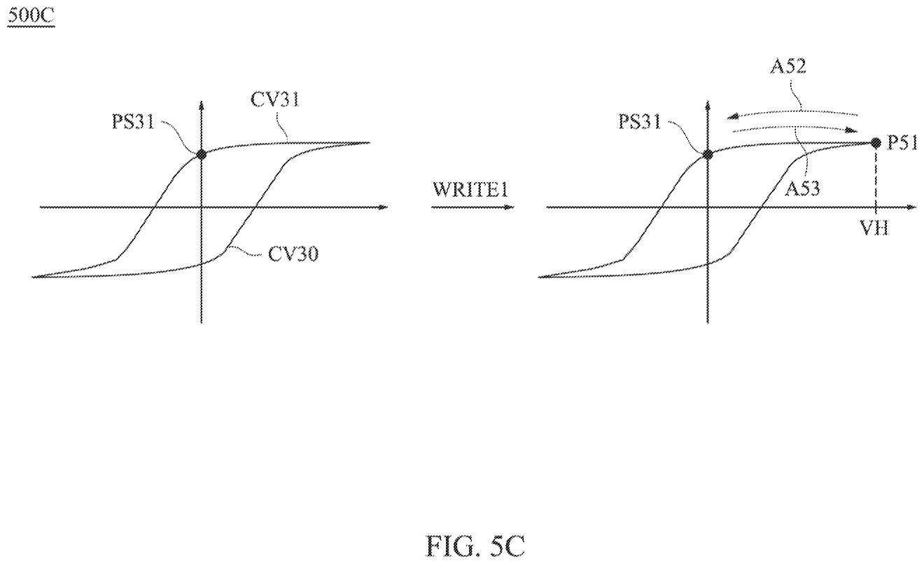

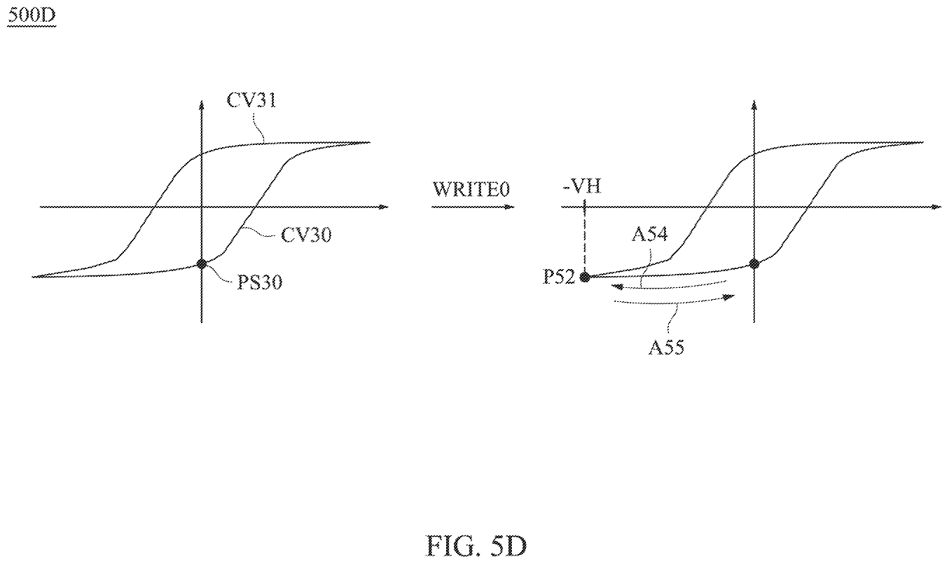

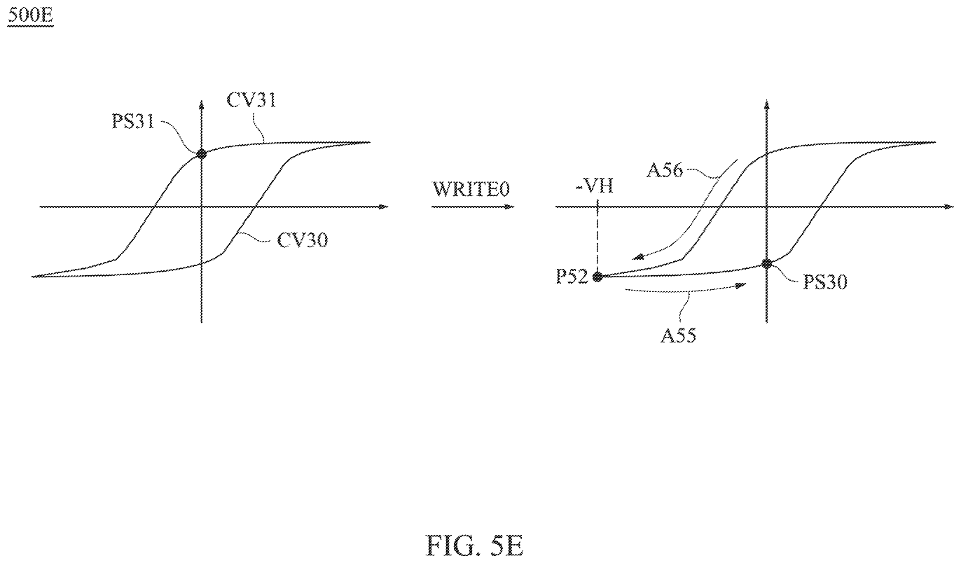

FIG. 5A is a timing diagram 500A of voltage levels of the word lines, the bit lines and the plate line shown in FIG. 1 during a write operation, in accordance with some embodiments of the present disclosure. A horizontal axis of the timing diagram 500A corresponds to time, and a vertical axis of the timing diagram 500A corresponds to voltage. As illustratively shown in FIG. 5A, the timing diagram 500A includes periods P51-P54 arranged continuously in order. Voltage levels of a bit line signal BLS, a selected word line signal SWLS, an unselected word line signal USWLS and a plate line signal PLS.

Referring to FIG. 5A and FIG. 1, the bit line signal BLS corresponds to the voltage level of one of the bit lines BL0-BL2. The selected word line signal SWLS corresponds to the voltage level of a selected one of the word lines WL0-WL3, and the unselected word line signal USWLS corresponds to the voltage level of the others of the word lines WL0-WL3. The plate line signal PLS corresponds to the voltage level of the plate line PL.

For illustration purpose, the bit line BL1, the word line WL1 and the memory element ME11 are described following as an example for explaining the bit line signal BLS and the selected word line signal SWLS. Alternatively stated, in the embodiment shown in FIG. 5A, the bit line signal BLS and selected word line signal SWLS are on the bit line BL1 and the word line WL1, respectively. However, the present disclosure is not limited to this. The features associated with the bit line signal BLS and the selected word line signal SWLS are also suitable for other bit lines, other word line and other memory elements.

During the period P51, each of the bit line signal BLS, the selected word line signal SWLS, the unselected word line signal USWLS and the plate line signal PLS has the ground voltage level VGND. Accordingly, the switches T00-T23 are turned off.

During the period P52, the selected word line signal SWLS is raised to the write voltage level VWL, such that the switches T01, T11 and T21 are turned on. In response to the bit line BL1 carrying the logic value 1, the bit line signal BLS is raised to a voltage level VH. At this moment, the plate line signal PLS is maintained at the ground voltage level VGND, such that the voltage difference between two terminals of the memory element ME11 is the voltage level VH. Accordingly, the logic value 1 is written into the memory element ME11. In some embodiments, the voltage level VH is larger than the coercive voltage level VC.

During the period P53, the selected word line signal SWLS is maintained at the write voltage level VWL, such that the switches T01, T11 and T21 are maintained to be turned on. In response to the bit line BL1 carrying the logic value 0, the bit line signal BLS is maintained at the ground voltage level VGND. At this moment, the plate line signal PLS is raised at the voltage level VH, such that the voltage difference between two terminals of the memory element ME11 is a voltage level −VH (that is, the negative of the voltage level VH). Accordingly, the logic value 0 is written into the memory element ME11. At the end of the period P53, the plate line signal PLS is adjusted to the ground voltage level VGND.

During the period P54, each of the bit line signal BLS and the selected word line signal SWLS is adjusted to the ground voltage level VGND. Accordingly, the switches T00-T23 are turned off, and the write operation is finished.

FIG. 5B is a schematic diagram 500B of relationship between voltage difference between two terminals of the memory element ME11 and polarization of the memory element ME11 during a write operation for writing the logic value 1, in accordance with some embodiments of the present disclosure. A horizontal axis of the schematic diagram 500B corresponds to voltage level, and a vertical axis of the schematic diagram 500B corresponds to polarization. The schematic diagram 500B corresponds to a condition that the memory element ME11 stores the logic value 0 before the write operation, and is written by the logic value 1 after the write operation.

Referring to FIG. 3 and FIG. 5B, the schematic diagram 500B is a specific embodiment of schematic diagram 300. FIG. 5B follows a similar labeling convention to that of FIG. 3. As illustratively shown in FIG. 5B, before the write operation, the memory element ME11 is at the point PS30 to store the logic value 0. During the write operation, in response to the voltage difference between two terminals of the memory element ME11 is adjusted to the voltage level VH, the state of the memory element ME11 is moved along an arrow A51 to a point P51 corresponding to the voltage level VH, and then is moved along an arrow A52 to the point PS31 to store the logic value 1.

FIG. 5C is a schematic diagram 500C of relationship between voltage difference between two terminals of the memory element ME11 and polarization of the memory element ME11 during a write operation for writing the logic value 1, in accordance with some embodiments of the present disclosure. A horizontal axis of the schematic diagram 500C corresponds to voltage level, and a vertical axis of the schematic diagram 500C corresponds to polarization. The schematic diagram 500C corresponds to a condition that the memory element ME11 stores the logic value 1 before the write operation, and is written by the logic value 1 after the write operation.

Referring to FIG. 3 and FIG. 5C, the schematic diagram 500C is a specific embodiment of schematic diagram 300. FIG. 5C follows a similar labeling convention to that of FIG. 3. As illustratively shown in FIG. 5C, before the write operation, the memory element ME11 is at the point PS31 to store the logic value 1. During the write operation, in response to the voltage difference between two terminals of the memory element ME11 is adjusted to the voltage level VH, the state of the memory element ME11 is moved along an arrow A53 to the point P51 corresponding to the voltage level VH, and then is moved along the arrow A52 to the point PS31 to store the logic value 1.

FIG. 5D is a schematic diagram 500D of relationship between voltage difference between two terminals of the memory element ME11 and polarization of the memory element ME11 during a write operation for writing the logic value 0, in accordance with some embodiments of the present disclosure. A horizontal axis of the schematic diagram 500D corresponds to voltage level, and a vertical axis of the schematic diagram 500D corresponds to polarization. The schematic diagram 500D corresponds to a condition that the memory element ME11 stores the logic value 0 before the write operation, and is written by the logic value 0 after the write operation.

Referring to FIG. 3 and FIG. 5D, the schematic diagram 500D is a specific embodiment of schematic diagram 300. FIG. 5D follows a similar labeling convention to that of FIG. 3. As illustratively shown in FIG. 5D, before the write operation, the memory element ME11 is at the point PS30 to store the logic value 0. During the write operation, in response to the voltage difference between two terminals of the memory element ME11 is adjusted to the voltage level −VH, the state of the memory element ME11 is moved along an arrow A54 to a point P52 corresponding to the voltage level −VH, and then is moved along an arrow A55 to the point PS30 to store the logic value 0.

FIG. 5E is a schematic diagram 500E of relationship between voltage difference between two terminals of the memory element ME11 and polarization of the memory element ME11 during a write operation for writing the logic value 0, in accordance with some embodiments of the present disclosure. A horizontal axis of the schematic diagram 500E corresponds to voltage level, and a vertical axis of the schematic diagram 500E corresponds to polarization. The schematic diagram 500E corresponds to a condition that the memory element ME11 stores the logic value 1 before the write operation, and is written by the logic value 0 after the write operation.

Referring to FIG. 3 and FIG. 5E, the schematic diagram 500E is a specific embodiment of schematic diagram 300. FIG. 5E follows a similar labeling convention to that of FIG. 3. As illustratively shown in FIG. 5E, before the write operation, the memory element ME11 is at the point PS31 to store the logic value 1. During the write operation, in response to the voltage difference between two terminals of the memory element ME11 is adjusted to the voltage level −VH, the state of the memory element ME11 is moved along an arrow A56 to the point P52 corresponding to the voltage level −VH, and then is moved along the arrow A55 to the point PS30 to store the logic value 0.

FIG. 6A is a cross section diagram of a memory device 600 corresponding to the memory device 100 shown in FIG. 1, in accordance with some embodiments of the present disclosure. As illustratively shown in FIG. 6A, the memory device 600 includes a substrate SB6, source/drain structures SD61-SD63, via structures V61-V66, gate structures GWL1, GWL2, conductive structures MBL1, MPL, electrodes TN61-TN63, a memory structure FR61 and a dielectric structure ILD6.

As illustratively shown in FIG. 6A, the source/drain structures SD61-SD63 are formed in the substrate SB6 and separated from each other along an X direction. The gate structures GWL1 and GWL2 are formed above and separated from the substrate SB6. Along a Z direction, parts of the dielectric structure ILD6 are formed above the substrate SB6 and under the gate structures GWL1 and GWL2, the conductive structure MBL1 is formed above the gate structures GWL1 and GWL2 and under the electrode TN62. In some embodiments, the X direction and the Z direction are perpendicular with each other.

In some embodiments, the source/drain structure SD61 is coupled to the electrode TN61 through the via structure V61. The source/drain structure SD63 is coupled to the electrode TN62 through the via structure V62. The source/drain structure SD62 is coupled to the conductive structure MBL1 through the via structure V63.

As illustratively shown in FIG. 6A, the electrode TN63 includes electrode portions TP61 and TP62. The memory structure includes FR61 includes memory portions FP61 and FP62. Each of the memory portions FP61, FP62 and the electrodes TN61, TN62 has an U shape. The memory portion FP61 is interposed between the electrode TN61 and the electrode portion TP61. The memory portion FP62 is interposed between the electrode TN62 and the electrode portion TP62.

In some embodiments, the memory portion FP61, the electrode TN61 and the electrode portion TP61 is configured to operate as a memory element ME61. The memory portion FP62, the electrode TN62 and the electrode portion TP62 is configured to operate as a memory element ME62.

As illustratively shown in FIG. 6A, the electrode TN63 is coupled to the conductive structure MPL through the via structures V64-V66. The via structure V64 is formed directly above the electrode portion TP61. The via structure V66 is formed directly above the electrode portion TP62. The via structure V65 is formed between the via structures V64 and V66 along the X direction. The dielectric structure ILD6 is formed between the elements described above.

In some embodiments, the substrate SB6 is implemented by silicon. The via structures V61-V66 and the conductive structures MBL1, MPL are implemented by metal. The gate structures GWL1 and GWL2 are implemented by gate material, such as poly-silicon. The electrodes TN61-TN63 are implemented by titanium nitride (TiN). The memory structure FR61 is implemented by ferroelectric material, such as hafnium zirconium oxide (HfZrOx) or hafnium silicon oxide (HfSiOx). The dielectric structure ILD6 is referred to as inter-layer dielectric or inter-metal dielectric, and is implemented by silicon oxide (SiOx) or other low-k dielectric material.

Referring to FIG. 1 and FIG. 6A, the memory device 600 is an embodiment of the memory device 100. In some embodiments, the bit line BL1, the word lines WL1, WL2, the plate line PL and the memory elements ME11 and ME12 are implemented by the conductive structure MBL1, the gate structures GWL1, GWL2, the conductive structure MPL and the memory elements ME61 and ME62. The source/drain structures SD61, SD62 and the gate structure GWL1 is configured to operate as a transistor corresponding to the switch T11. The source/drain structures SD63, SD62 and the gate structure GWL2 is configured to operate as a transistor corresponding to the switch T12.

In alternative embodiments, the switches T11 and T12 (and other switches in the memory device 100) are implemented by back-end-of-line (BEOL) compatible poly-silicon thin film transistor (TFT) or indium gallium zinc oxide (IGZO) TFT for three dimensional (3D) stacked ferroelectric random-access memory (FeRAM).

Referring to FIG. 3 and FIG. 6A, the shape of the curves CV30 and CV31 are associated with configurations of the memory structure FR61. In some embodiments, the curves CV30 and CV31 are changed according to a thickness of the memory structure FR61, a composition of the memory structure FR61 and interfaces between the memory structure FR61 and electrodes (such as the electrodes TN61-TN63). Alternatively stated, the signal differentiation SD3 is changed according to the thickness of the memory structure FR61, the composition of the memory structure FR61 and the interfaces between the memory structure FR61 and the electrodes.

FIG. 6B is a cross section diagram of the memory device 600 along a line L6 shown in FIG. 6A, in accordance with some embodiments of the present disclosure. As illustratively shown in FIG. 6B, the memory device 600 further includes source/drain structures SD64-SD65, isolation structures IS61, IS62, via structures V67-V610, conductive structures MBL2, MBL3 and electrodes TN64-TN65. The electrode TN63 further includes electrode portions TP63 and TP64. The memory structure FR61 further includes memory portions TP63 and TP64.

As illustratively shown in FIG. 6B, the source/drain structures SD63-SD65 are formed in the substrate SB6 and separated from each other along a Y direction. The isolation structure IS61 is formed in the substrate SB6 and configured to isolate the source/drain structures SD63 and SD64. The isolation structure IS62 is formed in the substrate SB6 and configured to isolate the source/drain structures SD65 and SD64. In some embodiments, the Y direction, the X direction and the Z direction are perpendicular with each other.

In some embodiments, the source/drain structure SD64 is coupled to the electrode TN64 through the via structure V67. The source/drain structure SD65 is coupled to the electrode TN65 through the via structure V68. Along the Y direction, the via structure V62, the conductive structure MBL1, the via structure V67, the conductive structure MBL2, the via structure V68 and the conductive structure MBL3 are arranged in order and are separated from each other.

As illustratively shown in FIG. 6B, each of the memory portions FP63, FP64 and the electrodes TN64, TN65 has an U shape. The memory portion FP63 is interposed between the electrode TN64 and the electrode portion TP63. The memory portion FP64 is interposed between the electrode TN65 and the electrode portion TP64.

In some embodiments, the memory portion FP63, the electrode TN64 and the electrode portion TP63 is configured to operate as a memory element ME63. The memory portion FP64, the electrode TN65 and the electrode portion TP64 is configured to operate as a memory element ME64.

As illustratively shown in FIG. 6B, the electrode TN63 is coupled to the conductive structure MPL through the via structures V69-V610. The via structure V69 is formed directly above the electrode portion TP63. The via structure V610 is formed directly above the electrode portion TP64.

Referring to FIG. 1 and FIG. 6A, in some embodiments, the bit line BL2 and the memory element ME12 is implemented by the conductive structure MBL2 and the memory element ME63. The source/drain structures SD63 and SD64 are configured to operate as two terminals of the switch T21.

FIG. 6C is a layout diagram of the memory device 600 shown in FIG. 6A, in accordance with some embodiments of the present disclosure. In FIG. 6C, the Z direction points out from the paper. As illustratively shown in FIG. 6C, each of the gate structures GWL1 and GWL2 are elongated along the Y direction. Each of the conductive structures MBL1 and MBL2 are elongated along the X direction. The conductive structure MPL extends along the X-Y plane.

In some embodiments, the conductive structure MPL is implemented by a sheet-like metal layer which covers all the memory cells in the same array, such as the memory cells MC00-MC23 shown in FIG. 1.

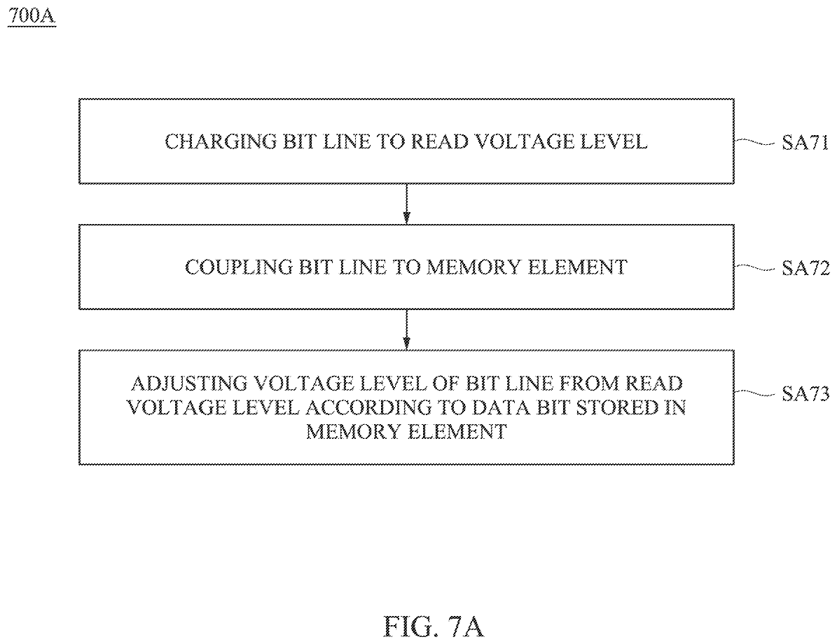

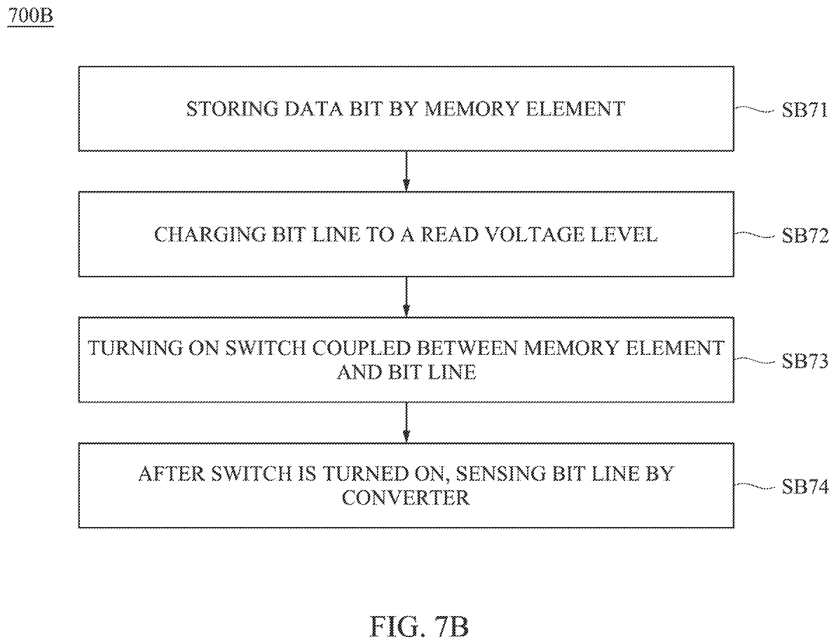

FIG. 7A is a flowchart diagram of a method 700A operating at least one of the memory devices 100 and 600 shown in FIG. 1 and FIG. 6A, in accordance with some embodiments of the present disclosure. As illustratively shown in FIG. 7A, the method 700A includes operations SA71-SA73.

During the operations SA71, a bit line is charged to the read voltage level VREAD1. For example, the bit line BL1 shown in FIG. 1 or the conductive structure MBL1 shown in FIG. 6A is charged to the read voltage level VREAD1.

During the operations SA72, the bit line is coupled to a memory element. For example, the bit line BL1 is coupled to the memory element ME11 through the switch T11. For another example, the memory element ME61 is coupled to the conductive structure MBL1 through the transistor corresponding to the source/drain structures SD61, SD62 and the gate structure GWL1.

During the operations SA73, a voltage level of the bit line is adjusted from the read voltage level VREAD1 according to a data bit stored in the memory element. For example, when each of the data bits stored in the memory elements ME10-ME13 has the logic value 0, the voltage level of the bit line BL1 is adjusted from the read voltage level VREAD1 to the voltage level VREAD0. When each of the data bits stored in the memory elements ME10-ME13 has the logic value 1, the voltage level of the bit line BL1 is maintained at the read voltage level VREAD1.

FIG. 7B is a flowchart diagram of a method 700B operating at least one of the memory devices 100 and 600 shown in FIG. 1 and FIG. 6A, in accordance with some embodiments of the present disclosure. As illustratively shown in FIG. 7B, the method 700B includes operations SB71-SB74.

During the operations SB71, a memory element stores a data bit. For example, the memory element ME11 shown in FIG. 1 or the memory element ME61 shown in FIG. 6A stores a data bit.

During the operations SB72, a bit line is charged to the read voltage level VREAD1. For example, during the period P22 shown in FIG. 2, the bit line BL1 shown in FIG. 1 or the conductive structure MBL1 shown in FIG. 6A is charged to the read voltage level VREAD1.

During the operations SB73, a switch coupled between the memory element and the bit line is turned on. For example, during the period P23, the switch T11 coupled between the memory element ME11 and the bit line BL1 is turned on. For another example, during the period P23, the transistor corresponding to the source/drain structures SD61, SD62 and the gate structure GWL1 is turned on, in which the transistor is coupled to the memory element ME61 and the conductive structure MBL1.

During the operations SB74, after the switch is turned on, a converter senses the bit line. For example, after the switch T11 is turned on, the converter ADC1 senses the bit line BL1.

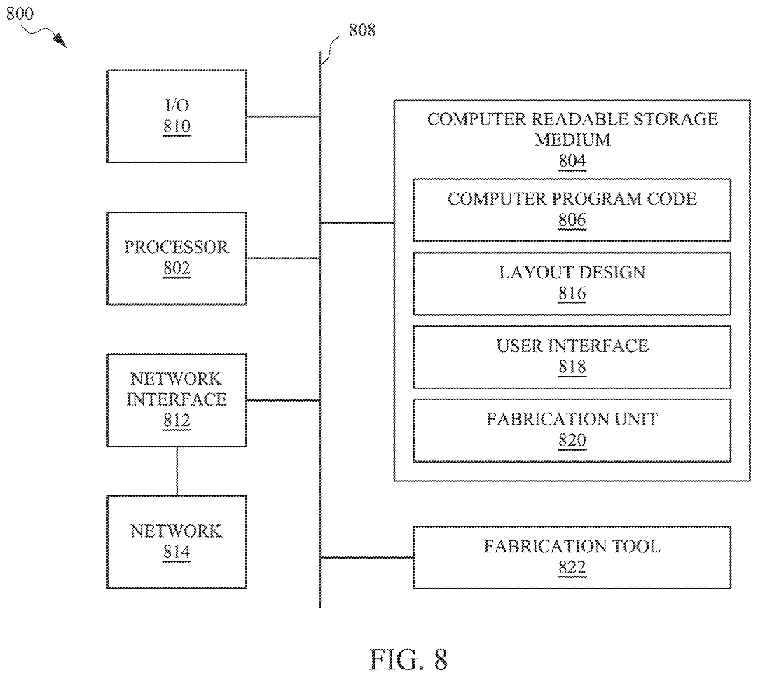

FIG. 8 is a schematic view of a system 800 for designing and manufacturing of at least one of the memory devices 100 and 600 shown in FIG. 1 and FIG. 6A, in accordance with some embodiments of the present disclosure. The system 800 generates or places one or more IC layout designs, as described herein. In some embodiments, the system 800 manufactures one or more semiconductor devices based on the one or more IC layout designs, as described herein. The system 800 includes a hardware processor 802 and a non-transitory, computer readable storage medium 804 encoded with, e.g., storing, the computer program code 806, e.g., a set of executable instructions. The computer readable storage medium 804 is configured for interfacing with manufacturing machines for producing the semiconductor device. The processor 802 is electrically coupled to the computer readable storage medium 804 by a bus 808. The processor 802 is also electrically coupled to an I/O interface 810 by the bus 808. A network interface 812 is also electrically connected to the processor 802 by the bus 808. Network interface 812 is connected to a network 814, so that the processor 802 and the computer readable storage medium 804 are capable of connecting to external elements via network 814. The processor 802 is configured to execute the computer program code 806 encoded in the computer readable storage medium 804 in order to cause the system 800 designing and manufacturing at least one of the memory devices 100 and 600.

In some embodiments, the processor 802 is a central processing unit (CPU), a multi-processor, a distributed processing system, an application specific integrated circuit (ASIC), and/or a suitable processing unit.

In some embodiments, the computer readable storage medium 804 is an electronic, magnetic, optical, electromagnetic, infrared, and/or a semiconductor system (or apparatus or device). For example, the computer readable storage medium 804 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 804 includes a compact disk-read only memory (CD-ROM), a compact disk-read/write (CD-R/W), and/or a digital video disc (DVD).

In some embodiments, the storage medium 804 also stores information needed for designing and manufacturing at least one of the memory devices 100 and 600, such as layout design 816, user interface 818, fabrication unit 820, and/or a set of executable instructions to perform the operation of designing and manufacturing at least one of the memory devices 100 and 600.

In some embodiments, the storage medium 804 stores instructions (e.g., the computer program code 806) for interfacing with manufacturing machines. The instructions (e.g., the computer program code 806) enable the processor 802 to generate manufacturing instructions readable by the manufacturing machines to effectively implement the designing and manufacturing at least one of the memory devices 100 and 600 during a manufacturing process.

The system 800 includes the I/O interface 810. The I/O interface 810 is coupled to external circuitry. In some embodiments, the I/O interface 810 includes a keyboard, keypad, mouse, trackball, trackpad, and/or cursor direction keys for communicating information and commands to the processor 802.

The system 800 also includes the network interface 812 coupled to the processor 802. The network interface 812 allows the system 800 to communicate with the network 814, to which one or more other computer systems are connected. The network interface 812 includes wireless network interfaces such as BLUETOOTH, WIFI, WIMAX, GPRS, or WCDMA; or wired network interface such as ETHERNET, USB, or IEEE-13154. In some embodiments, the designing and manufacturing at least one of the memory devices 100 and 600 is implemented in two or more systems 800, and information such as layout design, user interface and fabrication unit are exchanged between different systems 800 by the network 814.

The system 800 is configured to receive information related to a layout design through the I/O interface 810 or network interface 812. The information is transferred to the processor 802 by the bus 808 to determine a layout design for producing an IC. The layout design is then stored in the computer readable medium 804 as the layout design 816. The system 800 is configured to receive information related to a user interface through the I/O interface 810 or network interface 812. The information is stored in the computer readable medium 804 as the user interface 818. The system 800 is configured to receive information related to a fabrication unit through the I/O interface 810 or network interface 812. The information is stored in the computer readable medium 804 as the fabrication unit 820. In some embodiments, the fabrication unit 820 includes fabrication information utilized by the system 800.

In some embodiments, the designing and manufacturing at least one of the memory devices 100 and 600 is implemented as a standalone software application for execution by a processor. In some embodiments, the designing and manufacturing at least one of the memory devices 100 and 600 is implemented as a software application that is a part of an additional software application. In some embodiments, the designing and manufacturing at least one of the memory devices 100 and 600 is implemented as a plug-in to a software application. In some embodiments, the designing and manufacturing at least one of the memory devices 100 and 600 is implemented as a software application that is a portion of an EDA tool. In some embodiments, the designing and manufacturing at least one of the memory devices 100 and 600 is implemented as a software application that is used by an EDA tool. In some embodiments, the EDA tool is used to generate a layout design of the integrated circuit device. In some embodiments, the layout design is stored on a non-transitory computer readable medium. In some embodiments, the layout design is generated using a tool such as VIRTUOSO® available from CADENCE DESIGN SYSTEMS, Inc., or another suitable layout generating tool. In some embodiments, the layout design is generated based on a netlist which is created based on the schematic design. In some embodiments, the designing and manufacturing at least one of the memory devices 100 and 600 is implemented by a manufacturing device to manufacture an integrated circuit using a set of masks manufactured based on one or more layout designs generated by the system 800. In some embodiments, the system 800 includes a manufacturing device (e.g., fabrication tool 822) to manufacture an integrated circuit using a set of masks manufactured based on one or more layout designs of the present disclosure.

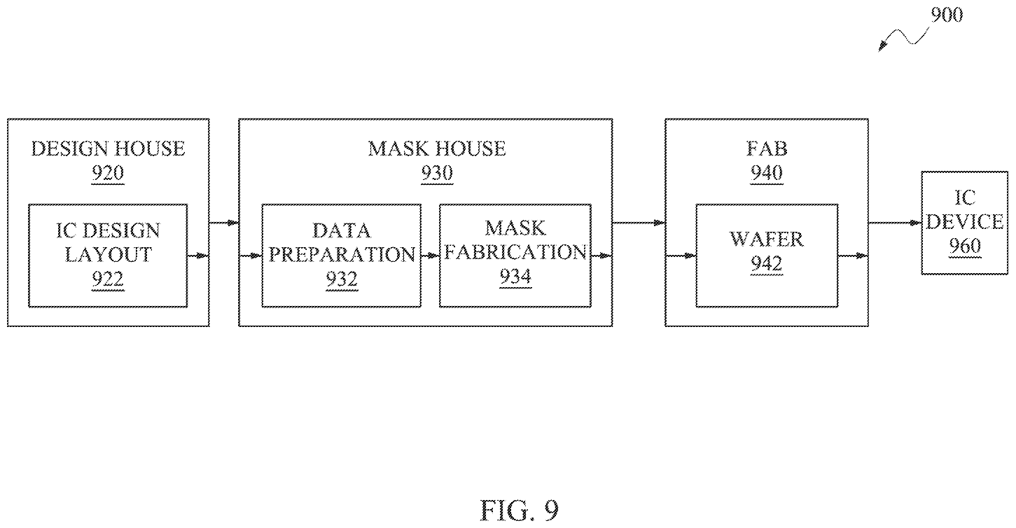

FIG. 9 is a block diagram of an integrated circuit (IC)/semiconductor device manufacturing system 900, and an IC manufacturing flow associated therewith, in accordance with some embodiments of the present disclosure.

In FIG. 9, the IC manufacturing system 900 includes entities, such as a design house 920, a mask house 930, and an IC manufacturer/fabricator (“fab”) 940, that interact with one another in the design, development, and manufacturing cycles and/or services related to manufacturing an IC device (semiconductor device) 960 including at least one of the memory devices 100 and 600. The entities in system 900 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 920, mask house 930, and IC fab 940 is owned by a single company. In some embodiments, two or more of design house 920, mask house 930, and IC fab 940 coexist in a common facility and use common resources.

The design house (or design team) 920 generates an IC design layout 922. The IC design layout 922 includes various geometrical patterns designed for the IC device 960. The geometrical patterns correspond to patterns of metal, oxide, or semiconductor layers that make up the various components of the IC device 960 to be fabricated. The various layers combine to form various IC features. For example, a portion of the IC design layout 922 includes various IC features, such as an active region, gate structures, source/drain structures, interconnect structures, and openings for bonding pads, to be formed in a semiconductor substrate (such as a silicon wafer) and various material layers disposed on the semiconductor substrate. The design house 920 implements a proper design procedure to form the IC design layout 922. The design procedure includes one or more of logic design, physical design or place and route. The IC design layout 922 is presented in one or more data files having information of the geometrical patterns. For example, the IC design layout 922 can be expressed in a GDSII file format or DFII file format.

The mask house 930 includes mask data preparation 932 and mask fabrication 934. The mask house 930 uses the IC design layout 922 to manufacture one or more masks to be used for fabricating the various layers of the IC device 960 according to the IC design layout 922. The mask house 930 performs the mask data preparation 932, where the IC design layout 922 is translated into a representative data file (“RDF”). The mask data preparation 932 provides the RDF to the mask fabrication 934. The mask fabrication 934 includes a mask writer. A mask writer converts the RDF to an image on a substrate, such as a mask (reticle) or a semiconductor wafer, or a metal layer which is formed and thereafter selectively etched to form a redistribution layer at a back end of line process of the fab. The design layout is manipulated by the mask data preparation 932 to comply with particular characteristics of the mask writer and/or requirements of the IC fab 940. In FIG. 9, the mask data preparation 932 and mask fabrication 934 are illustrated as separate elements. In some embodiments, the mask data preparation 932 and mask fabrication 934 can be collectively referred to as mask data preparation.

In some embodiments, the mask data preparation 932 includes optical proximity correction (OPC) which uses lithography enhancement techniques to compensate for image errors, such as those that can arise from diffraction, interference, other process effects and the like. OPC adjusts the IC design layout 922. In some embodiments, the mask data preparation 932 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 932 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during the mask fabrication 934, which may undo part of the modifications performed by OPC in order to meet mask creation rules.

In some embodiments, the mask data preparation 932 includes lithography process checking (LPC) that simulates processing that will be implemented by the IC fab 940 to fabricate the IC device 960. LPC simulates this processing based on the IC design layout 922 to create a simulated manufactured device, such as the IC device 960. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC can be repeated to further refine the IC design layout 922.

It should be understood that the above description of the mask data preparation 932 has been simplified for the purposes of clarity. In some embodiments, the mask data preparation 932 includes additional features such as a logic operation (LOP) to modify the IC design layout according to manufacturing rules. Additionally, the processes applied to the IC design layout 922 during the mask data preparation 932 may be executed in a variety of different orders.

After the mask data preparation 932 and during mask fabrication 934, a mask or a group of masks are fabricated based on the modified IC design layout. In some embodiments, an electron-beam (e-beam) or a mechanism of multiple e-beams is used to form a pattern on a mask (photomask or reticle) based on the modified IC design layout. The mask can be formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask can be attenuated PSM or alternating PSM. The mask(s) generated by the mask fabrication 934 is used in a variety of processes. For example, such a mask(s) is used in an ion implantation process to form various doped regions in the semiconductor wafer, in an etching process to form various etching regions in the semiconductor wafer, and/or in other suitable processes.

The IC fab 940 is an IC fabrication entity that includes one or more manufacturing facilities for the fabrication of a variety of different IC products. In some embodiments, the IC fab 940 is a semiconductor foundry. For example, there may be a first manufacturing facility for the front end fabrication of a plurality of IC products (e.g., source/drain structures, gate structures), while a second manufacturing facility may provide the middle end fabrication for the interconnection of the IC products (e.g., MDs, VDs, VGs) and a third manufacturing facility may provide the back end fabrication for the interconnection and packaging of the IC products (e.g., M0 tracks, M1 tracks, BM0 tracks, BM1 tracks), and a fourth manufacturing facility may provide other services for the foundry entity.

The IC fab 940 uses the mask (or masks) fabricated by the mask house 930 to fabricate the IC device 960. Thus, the IC fab 940 at least indirectly uses the IC design layout 922 to fabricate the IC device 960. In some embodiments, a semiconductor wafer is fabricated by the IC fab 940 using the mask (or masks) to form the IC device 960. The semiconductor wafer 942 includes a silicon substrate or other proper substrate having material layers formed thereon. Semiconductor wafer further includes one or more of various doped regions, dielectric features, multilevel interconnects, and the like (formed at subsequent manufacturing steps).

Also disclosed is a method. The method includes: charging a bit line to a read voltage level; coupling the bit line to a memory element; and adjusting a voltage level of the bit line from the read voltage level according to a data bit stored in the memory element. The read voltage level is smaller than a coercive voltage level of the memory element.

Also disclosed is a memory device. The memory device includes a first memory cell, a converter and a first bit line. The first memory cell configured to store a data bit. The converter configured to read the data bit. The first bit line coupled between the first memory cell and the converter. The first memory cell comprises a first switch and a first memory element, during a read operation, the first bit line is charged to a read voltage level, and the read voltage level is smaller than a coercive voltage level of the first memory element.

Also disclosed is a method. The method includes: storing a data bit by a memory element; charging a bit line to a read voltage level; turning on a switch coupled between the memory element and the bit line; and after the switch is turned on, sensing the bit line by a converter. The read voltage level is smaller than a voltage level, and when a voltage difference between two terminals of the memory element is approximately equal to the voltage level, a polarization of the memory element is approximately equal to zero.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
charging a bit line to a read voltage level;
coupling the bit line to a memory element; and
adjusting a voltage level of the bit line from the read voltage level according to a data bit stored in the memory element,
wherein the read voltage level is smaller than a coercive voltage level of the memory element.

2. The method of claim 1, wherein when a voltage difference between two terminals of the memory element is approximately equal to the coercive voltage level, a polarization of the memory element is approximately equal to zero.

3. The method of claim 1, further comprising:
sensing the bit line by a converter; and
determining the read voltage level according to a sensing resolution of the converter.

4. The method of claim 3, wherein when the converter has a first sensing resolution, the read voltage level has a first value, and
when the converter has a second sensing resolution higher than the first sensing resolution, the read voltage level has a second value lower than the first value.

5. The method of claim 1, further comprising:
calculating a signal differentiation according to a first polarization difference and a second polarization difference of the memory element; and
determining the read voltage level according to the signal differentiation,
wherein the first polarization difference and the second polarization difference correspond to a first logic value and a second logic value, respectively, and
the first logic value and the second logic value are different from each other.

6. The method of claim 5, wherein
the first polarization difference is a difference between a first polarization and a second polarization,
the second polarization difference is a difference between a third polarization and a fourth polarization,
each of the first polarization and the third polarization corresponds to a zero voltage level, and
each of the second polarization and the fourth polarization corresponds to the read voltage level.

7. The method of claim 6, wherein
in response to the signal differentiation having a first differentiation value, the read voltage level has a first value, and
in response to the signal differentiation having a second differentiation value larger than the first differentiation value, the read voltage level has a second value smaller than the first value.

8. The method of claim 1, wherein when a cell number of the bit line is increased, the read voltage level is decreased.

9. The method of claim 1, wherein the read voltage level is within a range from 0.3 times the coercive voltage level to 0.8 times the coercive voltage level.

10. A memory device, comprising:
a first memory cell configured to store a data bit;
a converter configured to read the data bit; and
a first bit line coupled between the first memory cell and the converter,
wherein the first memory cell comprises a first switch and a first memory element,
during a read operation, the first bit line is charged to a read voltage level, and
the read voltage level is smaller than a coercive voltage level of the first memory element.

11. The memory device of claim 10, wherein when a voltage difference between two terminals of the first memory element is approximately equal to the coercive voltage level, a polarization of the first memory element is approximately equal to zero.

12. The memory device of claim 11, further comprising:
a second memory cell coupled to the first bit line and comprising a second switch and a second memory element; and
a plate line coupled to each of the first memory element and the second memory element, and maintained at a ground voltage level during the read operation.

13. The memory device of claim 12, further comprising:
a first word line coupled to a control terminal of the first switch; and
a second word line coupled to a control terminal of the second switch,
wherein the first bit line is located between the plate line and each of the first word line and the second word line.

14. The memory device of claim 13, further comprising:
a third memory cell coupled to the plate line and the first word line; and
a second bit line coupled to the third memory cell and having the read voltage level during the read operation.

15. The memory device of claim 11, wherein when a sensing resolution of the converter is increased, the read voltage level is decreased.

16. The memory device of claim 15, wherein the read voltage level is within a range from 0.3 times the coercive voltage level to 0.8 times the coercive voltage level.

17. A method, comprising:
storing a data bit by a memory element;
charging a bit line to a read voltage level;
turning on a switch coupled between the memory element and the bit line; and
after the switch is turned on, sensing the bit line by a converter,
wherein the read voltage level is smaller than a voltage level, and
when a voltage difference between two terminals of the memory element is approximately equal to the voltage level, a polarization of the memory element is approximately equal to zero.

18. The method of claim 17, further comprising:
decreasing the read voltage level when a sensing resolution of the converter is increased.

19. The method of claim 17, further comprising:
calculating a signal differentiation of the memory element according to a first polarization, a second polarization, a third polarization and a fourth polarization; and
decreasing the read voltage level when the signal differentiation is increased,
wherein each of the first polarization and the second polarization corresponds to a first logic value,
each of the third polarization and the fourth polarization corresponds to a second logic value different from the first logic value,
each of the first polarization and the fourth polarization corresponds to the voltage difference being a zero voltage level, and
each of the first polarization and the fourth polarization corresponds to the voltage difference being the read voltage level.

20. The method of claim 19, wherein the signal differentiation is changed according to at least one of a thickness of a memory structure in the memory element, a composition of the memory structure and interfaces of the memory element.
